(19) United States
(12) Patent Application Publication
(10) Pub. No.: US 2026/0211276 A1
(43) Pub. Date: Jul. 23, 2026

(54) DISPLAY DEVICE

(71) Applicant: LG ELECTRONICS INC., Seoul (KR)

(72) Inventor: Hyunjung KANG, Seoul (KR)

(73) Assignee: LG ELECTRONICS INC., Seoul (KR)

(21) Appl. No.: 19/138,993

(22) PCT Filed: Dec. 16, 2022
(86) PCT No.: PCT/KR2022/020632

§ 371 Date: Jun. 13, 2025

(51) Int. Cl. G02F 1/1333; H05K 9/00

(52) U.S. Cl. CPC G02F 1/133314; H05K 9/0009

(57) ABSTRACT

According to an aspect of the present disclosure to achieve the objective described above, a display device includes: a display panel; a frame to which the display panel is coupled; a back cover coupled to the frame and opposite the display panel with respect to the frame; and a rigid part positioned between the frame and the back cover, attached to the back cover, and elongated in a length direction of one side of the display panel, wherein the rigid part includes a base to be attached to the back cover, and a protrusion protruding from the base toward a thickness direction of the back cover.

### CROSS REFERENCE TO RELATED APPLICATIONS

This application is the National Phase of PCT International Application No. PCT/KR2022/020632, filed on Dec. 16, 2022, all of which is hereby expressly incorporated by reference into the present application.

### BACKGROUND

### Technical Field

The present disclosure relates to a display device.

### Discussion of the Related Art

With the development of information society, there has been a growing demand for various types of display devices. In order to meet such demand, various display devices, such as a liquid crystal display (LCD) device, a plasma display panel (PDP), an electro luminescent display (ELD), a vacuum fluorescent display (VFD), and the like, have been developed and used.

Among them, an LCD panel includes a TFT substrate and a color substrate that are opposite each other with a liquid crystal layer interposed therebetween, and can display an image using light provided from a backlight unit.

Recently, research on a structure that ensures the rigidity of a display device has been actively conducted.

### SUMMARY

It is an object of the present disclosure to solve the above and other problems.

Another object may be to provide a structure that ensures the rigidity of a display device.

Another object may be to provide a structure that ensures the rigidity of a back cover.

Another object may be to provide a rigid bar structure that can prevent the occurrence of lifting between a back cover and a rigid bar.

Another object may be to provide a display device that can reduce EMI noise.

In accordance with an aspect of the present disclosure for achieving the above and other objects, a display device includes: a display panel; a frame to which the display panel is coupled; a back cover coupled to the frame and opposite the display panel with respect to the frame; and a rigid part disposed between the frame and the back cover, attached to the back cover, and elongated in a longitudinal direction of one side of the display panel, wherein the rigid part includes: a base attached to the back cover; and a protruding part protruding from the base in a thickness direction of the back cover.

### Advantageous Effects

A display device according to the present disclosure has the following effects.

According to at least one of the embodiments of the present disclosure, it is possible to provide a structure that ensures the rigidity of a display device.

According to at least one of the embodiments of the present disclosure, it is possible to provide a structure that ensures the rigidity of a back cover.

According to at least one of the embodiments of the present disclosure, it is possible to provide a rigid bar structure capable of preventing the occurrence of lifting between a back cover and a rigid bar.

According to at least one of the embodiments of the present disclosure, it is possible to provide a display device capable of reducing EMI noise.

Further scope of applicability of the present disclosure will become apparent from the following detailed description. However, it should be understood that the detailed description and specific embodiments such as preferred embodiments of the present disclosure are given by way of example only, since various changes and modifications within the idea and scope of the present disclosure may be clearly understood by those skilled in the art.

### BRIEF DESCRIPTION OF THE DRAWING

FIGS. 1 to 12 are diagrams illustrating examples of a display device according to embodiments of the present disclosure.

### DETAILED DESCRIPTION OF THE EMBODIMENTS

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In the following description, a suffix such as “module” and “unit” may be used to refer to elements or components. Use of such a suffix herein is merely intended to facilitate description of the specification, and the suffix itself is not intended to give any special meaning or function.

In the present disclosure, that which is well known to one of ordinary skill in the relevant art has generally been omitted for the sake of brevity. The accompanying drawings are used to help easily understand various technical features and it should be understood that the embodiments disclosed herein are not limited by the accompanying drawings. As such, the present disclosure should be construed to extend to any alterations, equivalents, and substitutes in addition to those which are particularly set out in the accompanying drawings.

Although the terms “first”, “second”, etc. may be used herein to describe various elements, these elements should not be limited by these terms. These terms are only used to distinguish one element from another.

It will be understood that when a component is referred to as being “coupled” or “connected” to another component, it may be directly coupled or connected to another component, or intervening components may be present. In contrast, when a component is referred to as being “directly coupled” or “directly connected” to another component, there are no intervening components present.

A singular representation may include a plural representation unless the context clearly indicates otherwise.

In the following description, if an embodiment is described with reference to a specific figure, reference numeral not shown in the specific figure may be mentioned, if necessary or desired. However, the reference numeral not shown in the specific figure may be mentioned only when the reference numeral is shown in other figures.

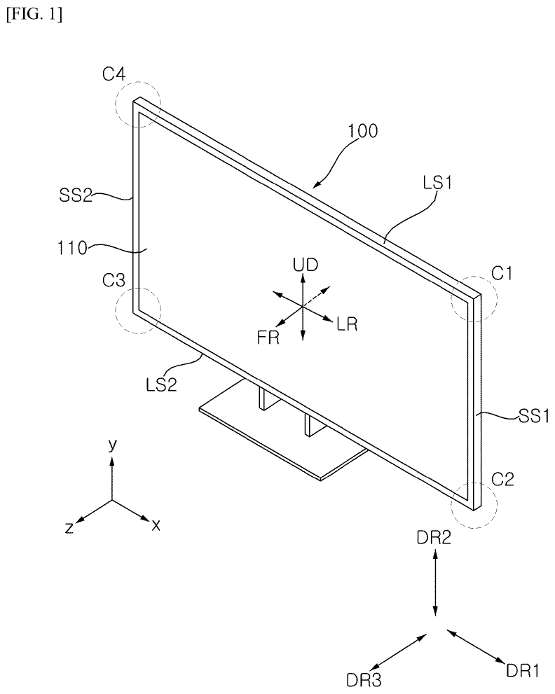

Referring to FIG. 1, a display device 100 may include a display panel 110. The display panel 110 may display an image.

The display device 100 may include a first long side LS1, a second long side LS2 opposite the first long side LS1, a first short side SS1 adjacent to the first long side LS1 and the second long side LS2, and a second short side SS2 opposite the first short side SS1. For ease of explanation, it is illustrated and described that lengths of the first and second long sides LS1 and LS2 are greater than lengths of the first and second short sides SS1 and SS2. However, the lengths of the first and second long sides LS1 and LS2 may be substantially equal to the lengths of the first and second short sides SS1 and SS2.

A direction parallel to the long sides LS1 and LS2 of the display device 100 may be referred to as a first direction DR1 or a left-and-right direction (LR). A direction parallel to the short sides SS1 and SS2 of the display device 100 may be referred to as a second direction DR2 or an up-and-down direction (UD). A direction perpendicular to the long sides LS1 and LS2 and the short sides SS1 and SS2 of the display device 100 may be referred to as a third direction DR3 or a front-and-rear direction (FR). Here, a direction in which the display panel 110 displays an image may be referred to as a front, and a direction opposite to the front may be referred to as a rear.

The first long side LS1 may be referred to as an upper side or an upper surface. The second long side LS2 may be referred to as a lower side or a lower surface. The first short side SS1 may be referred to as a left side or a left surface. The second short side SS2 may be referred to as a right side or a right surface.

The first long side LS1, the second long side LS2, the first short side SS1, and the second short side SS2 may be referred to as edges of the display device 100. In addition, points where the first long side LS1, the second long side LS2, the first short side SS1, and the second short side SS2 meet one another may be referred to as corners.

For example, a point where the first long side LS1 and the first short side SS1 meet may be referred to as a first corner C1; a point where the first short side SS1 and the second long side LS2 meet may be referred to as a second corner C2; a point where the second long side LS2 and the second short side SS2 meet may be referred to as a third corner C3; and a point where the second short side SS2 and the first long side LS1 meet may be referred to as a fourth corner C4.

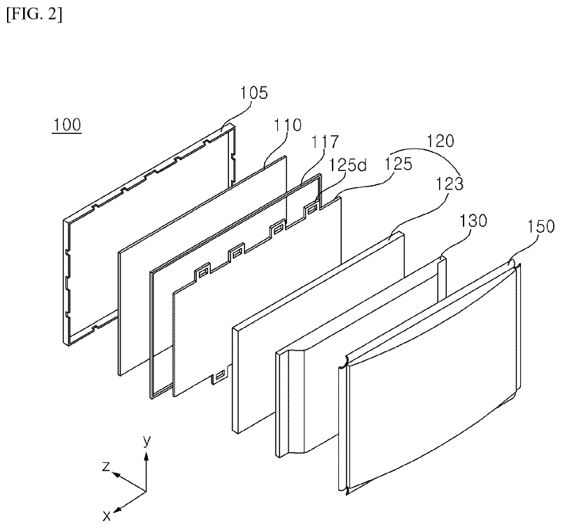

Hereinafter, an example in which the display device 100 includes an LCD panel as the display panel 110 will be described with reference to FIGS. 2 to 4. However, the display device 100 according to the present disclosure may include other various panels such as an OLED panel as the display panel 110.

Referring to FIG. 2, the display device 100 may include a front cover 105. The front cover 105 may cover at least a portion of a front surface and a lateral surface of the display panel 110. The front cover 105 may be divided into a front cover disposed on the front surface of the display panel 110, and a side cover disposed on the lateral surface of the display panel 110. The front cover and the side cover may be provided separately. Any one of the front cover and the side cover may be omitted.

The display device 100 may include the display panel 110. The display panel 110 may be an LCD panel. The display panel 110 may be provided on the front surface of the display device 100 and may display an image. The display panel 110 may display an image in such a manner that each of a plurality of pixels outputs red, green or blue (RGB) light in accordance with timing. The display panel 110 may be divided into an active area in which an image is displayed and a de-active area in which no image is displayed. The display panel 110 may include a front substrate and a rear substrate that are opposite each other with a liquid crystal layer interposed therebetween.

The front substrate may include a plurality of pixels, each of which consists of red, green, and blue sub-pixels. The front substate may output light corresponding to red, green or blue color in response to a control signal.

The rear substrate may include switching elements. The rear substrate may switch a pixel electrode. For example, the pixel electrode may change the molecular arrangement of a liquid crystal layer in response to a control signal input from the outside. The liquid crystal layer may include liquid crystal molecules. The arrangement of liquid crystal molecules may be changed according to a voltage difference between the pixel electrode and a common electrode. The liquid crystal layer may transmit light provided from a backlight unit 120 to the front substrate or block the light.

The display device 100 may include a guide panel 117. The guide panel 117 may be positioned at the rear of the display panel 110. The guide panel 117 may support a portion of a rear surface of the display panel 110. The guide panel 117 may be in contact with an outer edge of the display panel 110. The guide panel 117 may be coupled to a frame 130 described later.

The display device 100 may include the backlight unit 120. The backlight unit 120 may be positioned at the rear of the display panel 110. The backlight unit 120 may include light sources. The backlight unit 120 may be coupled to the frame 70 at the front of the frame 130. The backlight unit 120 may be driven by a full driving scheme or a partial driving scheme such as local dimming or impulsive driving. The backlight unit 120 may include an optical sheet 125 and an optical layer 123.

The optical sheet 125 may allow light from the light source to be uniformly transmitted to the display panel 110. The optical sheet 125 may consist of a plurality of layers. For example, the optical sheet 125 may include a prism sheet, a diffusion sheet, and the like.

The optical sheet 125 may include a coupling part 125d. The coupling part 125d may be coupled to the front cover 105, the frame 130, and/or a back cover 150. The coupling part 125d may be coupled to a structure that is formed on or coupled to the front cover 105, the frame 130, and/or the back cover 150.

The display device 100 may include the frame 130. The frame 130 may be positioned behind the display panel 110. The frame 130 may support some components of the display device 100. For example, the backlight unit 120, a printed circuit board (PCB) on which a plurality of electronic elements are mounted, and the like may be coupled or fixed to the frame 130. The frame 130 may include a metal material such as stainless steel, aluminum alloy, electro galvanized coil (EGI), etc. Meanwhile, the frame 130 may be referred to as a main frame, an inner frame, or a module cover.

The display device 100 may include the back cover 150. The back cover 150 may be positioned at the rear of the frame 130, and may cover the rear of the frame 130. The back cover 150 may define the rear surface of the display device 100. The back cover 150 may be coupled to the frame 130 and/or the front cover 105. For example, the back cover 150 may include a metal material.

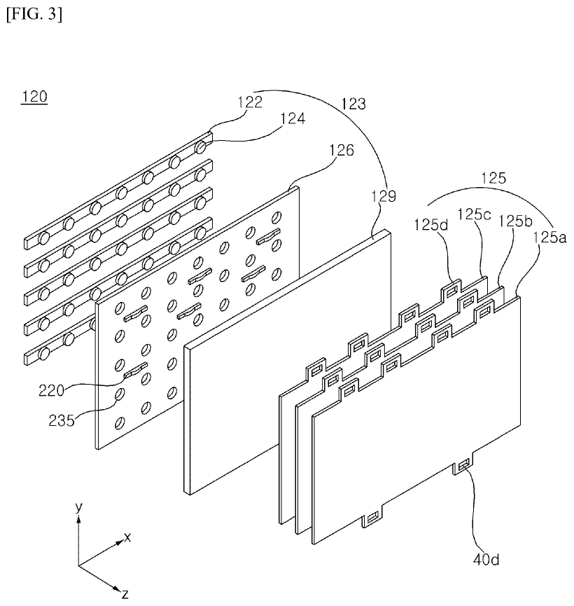

Referring to FIG. 3, the backlight unit 120 may include an optical layer 123 and an optical sheet 125.

The optical layer 123 may include a substrate 122. The substrate 122 may be provided in the form of a plurality of straps that extend in the left-and-right direction (LR) and are spaced apart from each other in the up-and-down direction (UD). At least one light assembly 124 may be mounted on the substrate 122. An electrode pattern for connecting an adapter and the light assembly 124 may be formed on the substrate 122. For example, a carbon nanotube (CNT) electrode pattern may be formed on the substrate 122 to connect the light assembly 124 and the adapter.

The substrate 122 may be made of at least one of polyethylene terephthalate (PET), glass, polycarbonate (PC), and silicon. The substrate 122 may be a printed circuit board (PCB) on which at least one light assembly 124 is mounted.

The optical layer 123 may include at least one light assembly 124. The light assembly 124 may be a light emitting diode (LED) chip or an LED package including at least one LED chip. The light assembly 124 may consist of a colored LED that emits at least one of red, green and blue light, or a white LED. The colored LED may include at least one of a red LED, a green LED, and a blue LED.

The optical layer 123 may include a reflective sheet 126. The reflective sheet 126 may be positioned at the front of the substrate 122. The reflective sheet 126 may include a plurality of through-holes 235 in which the light assembly 124 is positioned. The reflective sheet 126 may reflect light, which is emitted from the light assembly 124 or reflected from a diffusion plate 129, forward. For example, the reflective sheet 126 may include a metal and/or a metal oxide having a high reflectance such as at least one of aluminum (Al), silver (Ag), gold (Au), and titanium dioxide (TiO2).

The optical layer 123 may include the diffusion plate 129. An air gap may be formed between the reflective sheet 126 and the diffusion plate 129. The air gap may serve as a buffer to allow light emitted from the light assembly 124 to spread widely. A supporter 200 may be disposed between the reflective sheet 126 and the diffusion plate 129 so as to form the air gap.

The diffusion plate 129 may be positioned at the front of the reflective sheet 126. The diffusion plate 129 may be disposed between the reflective sheet 126 and the optical sheet 125.

The optical sheet 125 may be positioned at the front of the optical layer 123. The optical sheet 125 may include one or more sheets. In detail, the optical sheet 125 may include one or more prism sheets and/or one or more diffusion sheets. The plurality of sheets included in the optical sheet 125 may be in an adhered and/or close contact state.

The optical sheet 125 may include a plurality of sheets having different functions. For example, the optical sheet 125 may include a first optical sheet 125a, a second optical sheet 125b, and a third optical sheet 125c. For example, the first optical sheet 125a may be a diffusion sheet, and the second optical sheet 125b and the third optical sheet 125c may be prism sheets. The number and/or position of diffusion sheets and prism sheets may vary. The diffusion sheet may prevent light from the diffusion plate 129 from being partially concentrated, thereby achieving more uniform distribution of light. The prism sheet may collect light from the diffusion plate 129 and provide the light to the display panel 110.

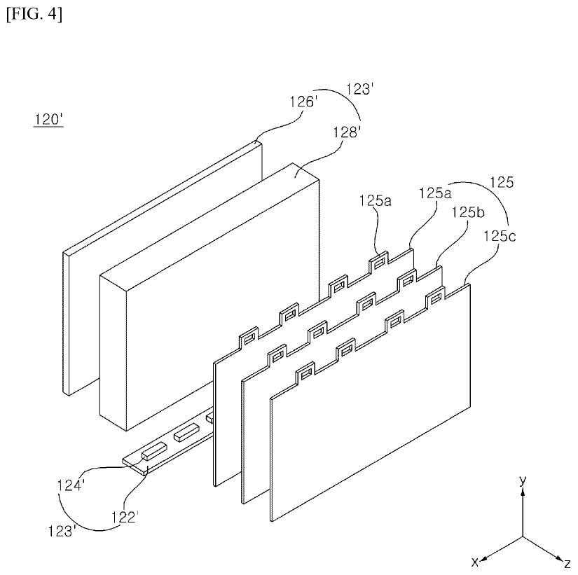

Referring to FIG. 4, a backlight unit 120′ may be provided at its edge with a light source. The backlight unit 120′ may include an optical layer 123′ that includes a substrate 122′, at least one light assembly 124′, a reflective sheet 126′ and a light guide plate 128′, and an optical sheet 125 that is positioned at the front of the optical layer 123′.

The substrate 122′ may extend in the left-and-right direction (LR), and may be adjacent to a lower side of the light guide plate 128′. At least one assembly 124′ may be mounted on the substrate 122′. Accordingly, most of the light emitted from the light assembly 124′ may be transmitted to the inside of the light guide plate 128′. Here, the light guide plate 128′ may reflect light incident from the light assembly 124′ forward. For example, a diffusion plate may be provided on a front surface of the light guide plate 128′.

The reflective sheet 126′ may be positioned at the rear of the light guide plate 128′. The reflective sheet 126′ may reflect light, emitted from the light assembly 124′ or reflected from the light guide plate 128′, forward.

An air gap may be formed between the light guide plate 128′ and the optical sheet 125. The air gap may serve as a buffer to allow light emitted from the optical assembly 124′ to spread widely.

The optical sheet 125 may be positioned at the front of the light guide plate 128′. A rear surface of the optical sheet 125 may be in close contact with the light guide plate 128′, and a front surface of the optical sheet 125 may be in close contact with the rear surface of the display panel 110.

A coupling part 125d may be formed on at least one edge of the optical sheet 125. The coupling part 125d may be formed on at least one of the first optical sheet 125a, the second optical sheet 125b, and the third optical sheet 125c.

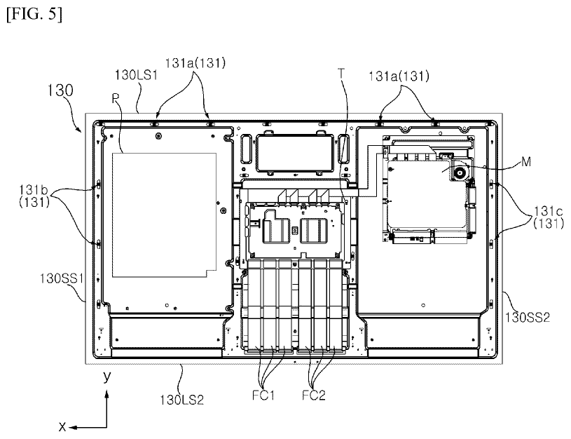

Referring to FIG. 5, a plurality of electronic components may be installed on the frame 130. The plurality of electronic components may be coupled or fixed to a rear surface of the frame 130.

For example, the plurality of electronic components may include a power supply board P configured to provide power to each component of the display device 100, a timing controller board T configured to provide an image (or video) signal to the display panel 110 (see FIG. 1), and a main board M configured to control each component of the display device 100. In this case, the timing controller board T may be connected to the display panel 110 via FFC cables FC1 and FC2. The plurality of electronic components may be electrically connected to each other, or may be electrically connected to each component of the display device 100.

The frame 130 may have a generally rectangular plate shape. An upper side 130LS1 of the frame 130 may extend in the left-and-right direction. A lower side 130LS2 of the frame 130 may be opposite the upper side 130LS1, and may extend in the left-and-right direction. A left side 130SS1 of the frame 130 may extend in the up-and-down direction. A right side 130SS2 of the frame 130 may be opposite the left side 130SS1, and may extend in the up-and-down direction. Meanwhile, the upper side 130LS1, the lower side 130LS2, the left side 130SS1, and the right side 130SS2 of the frame 130 may be referred to as edges of the frame 130.

A holding part 131 may be positioned adjacent to the edge of the frame 130. A plurality of holding parts 131 may be provided. The plurality of holding parts 131 may be spaced apart from each other along the periphery of the frame 130. The plurality of holding parts 131 may include a first holding part 131a disposed adjacent to the upper side 130LS1 of the frame 130, a second holding part 131b disposed adjacent to the left side 130SS1 of the frame 130, and a third holding part 131c disposed adjacent to the right side 130SS2 of the frame 130. The first holding part 131a may be provided in plurality to be spaced apart from each other along a longitudinal direction of the upper side 130LS1 of the frame 130. The second holding part 131b may be provided in plurality to be spaced apart from each other along a longitudinal direction of the left side 130SS1 of the frame 130. The third holding part 131c may be provided in plurality to be spaced apart from each other along a longitudinal direction of the right side 130SS2 of the frame 130.

The holding part 131 may include a fourth holding part (not shown) disposed adjacent to the lower side 130LS2 of the frame 130. The fourth holding part (not shown) may be provided in plurality to be spaced apart from each other along a longitudinal direction of the lower side 130LS2 of the frame 130.

The back cover 150 (see FIG. 2) may be coupled to the edges of the frame 130. The back cover 150 (see FIG. 2) may be coupled to the holding part 131.

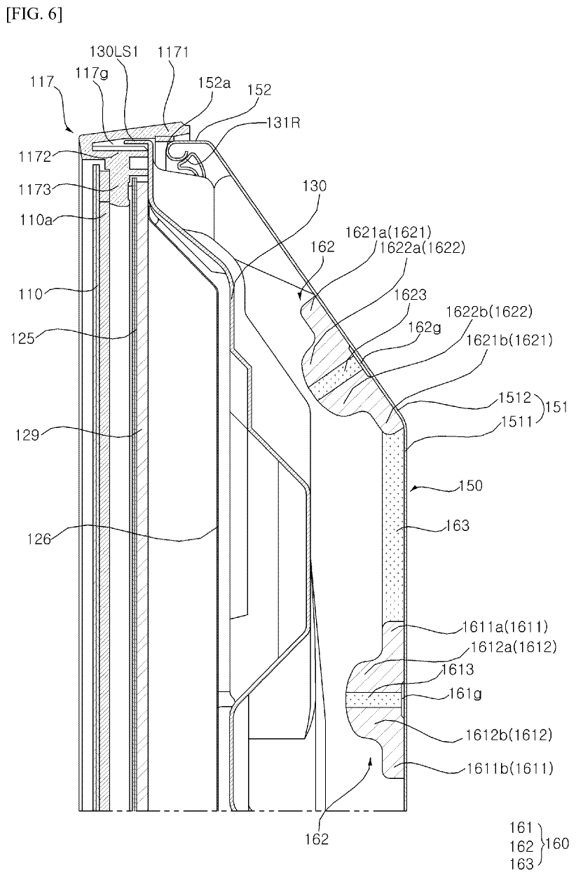

Referring to FIG. 6, the guide panel 117 may define the side surface of the display device 100. The guide panel 117 may be coupled with the frame 130. The guide panel 117 may cover a side surface of the frame 130. A portion of the frame 130 that forms an outer edge of the frame 130 may be inserted into the guide panel 117. The frame 130 may be fixed or secured to the guide panel 117. The guide panel 117 may cover a side surface of the display panel 110, and may support a portion of the rear surface of the display panel 110.

The guide panel 117 may include a horizontal portion 1171, 1172 and a vertical portion 1173. The horizontal portion 1171, 1172 may cover the side surface of the display panel 110. The horizontal portion 1171, 1172 may be coupled to the frame 130. The horizontal portion 1171, 1172 may include a first horizontal portion 1171 and a second horizontal portion 1172. The first horizontal portion 1171 may be positioned over the second horizontal portion 1172. A slit 117g may be formed between the first horizontal portion 1171 and the second horizontal portion 1172. The frame 130 may be inserted into and coupled to the slit 117g. The edge of the frame 130 may be inserted into and coupled to the slit 117g. The vertical portion 1173 may extend downward from the horizontal portion 1171, 1172. The vertical portion 1173 may extend downward from the second horizontal portion 1172. The vertical portion 1173 may be positioned at the rear of the display panel 110, and may face an edge of the display panel 110.

A foam pad 110a may be positioned at the front of the vertical portion 1173, and may be coupled to the vertical portion 1173. The foam pad 110a may be coupled to the display panel 110 and the vertical portion 1173 between the display panel 110 and the vertical portion 1173.

The optical sheet 125 may be positioned at the rear of the vertical portion 1173, and may be coupled to the vertical portion 1173. The diffusion plate 129 may be positioned at the rear of the optical sheet 125. The optical sheet 125 and the diffusion plate 129 may be disposed opposite the foam pad 110a with respect to the vertical portion 1173. The optical sheet 125 and the diffusion plate 129 may be disposed opposite the display panel 110 with respect to the vertical portion 1173. A rim (no reference numeral) of the reflective sheet 126 (see FIG. 3) may contact a rear surface of the diffusion plate 129, and the remaining portion of the reflective sheet 126 may extend obliquely rearward from the rim.

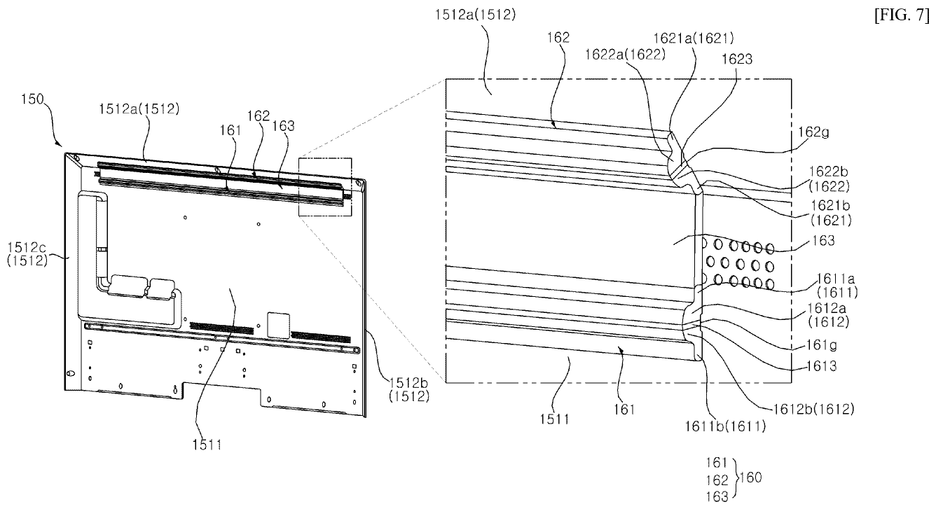

Referring to FIGS. 6 and 7, the back cover 150 may be coupled to the frame 130 at the rear of the frame 130. The back cover 150 may be coupled to the holding part 131 (see FIG. 5) of the frame 130.

The back cover 150 may include a cover part 151. The cover part 151 may form a rear surface of the back cover 150. The cover part 151 may include a first cover part 1511 that is formed flat, and a second cover part 1512 that extends from the first cover part 1511 and is formed in an inclined manner.

The first cover part 1511 may be a rectangular thin plate. The first cover part 1511 may be parallel to the display panel 110. The first cover part 1511 may be spaced rearward from the frame 130. An upper side 1511LS1 of the first cover part 1511 may extend horizontally. A lower side 1511LS2 of the first cover part 1511 may extend horizontally, and may be opposite the upper side 1511S1. A left side 1511SS1 of the first cover part 1511 may extend vertically, and may connect the upper side 1511LS1 and the lower side 1511LS2. Aright side 1511SS2 of the first cover part 1511 may be opposite the left side 1511SS1, may extend vertically, and may connect the upper side 1511LS1 and the lower side 1511LS2. Meanwhile, the upper side 1511LS1, the lower side 1511LS2, the left side 1511SS1, and the right side 1511SS2 of the first cover part 1511 may be referred to as edges of the first cover part 1511.

The second cover part 1512 may extend from the edge of the first cover part 1511. The second cover part 1512 may extend in a direction in which the first cover part 1511 faces the display panel 110. The second cover part 1512 may form an obtuse angle with respect to the first cover part 1511.

For example, the second cover part 1512 may include a front part 1512a extending from the upper side 1511LS1 of the first cover part 1511, a first side part 1512b extending from the left side 1511SS1 of the first cover part 1511, and a second side part 1512c extending from the right side 1511SS2 of the first cover part 1511. The second cover part 1512 may include a lower part (not shown) extending from the lower side 1511LS2 of the first cover part 1511.

The back cover 150 may include a coupling part 152. The coupling part 152 may be formed at an end of the second cover part 1512. The coupling part 152 may be formed by extending forward from the end of the second cover part 1512. The coupling part 152 may be coupled to the holding part 131 of the frame 130.

The coupling part 152 may include an engaging portion 152a formed by curling from an end of the coupling part 152 toward an inner surface of the coupling part 152. The engaging portion 152a may be coupled to the holding part 131. The engaging portion 152a may be coupled to a seating portion 131R of the holding part 131. The seating portion 131R of the holding part 131 may be formed in a curved shape (i.e., formed with a curvature). The seating portion 131R of the holding part 131 may have a curvature corresponding to a curvature of the engaging portion 152a.

The display device 100 may include a rigid part 160. The rigid part 160 may be coupled to the back cover 150. The rigid part 160 may be coupled to an inner surface of the back cover 150. For example, the rigid part 160 may be positioned adjacent to the upper side 1511LS1 or the lower side 1511LS2 of the first cover part 1511. In this case, the rigid part 160 may be horizontally elongated. For example, the rigid part 160 may be positioned adjacent to the left side 1511SS1 or the right side 1511SS2 of the first cover part 1511. In this case, the rigid part 160 may be vertically elongated.

The rigid part 160 may be provided in plurality. In this case, the rigid part 160 may be provided at least one of a position adjacent to the upper side 1511LS1 of the first cover part 1511, a position adjacent to the lower side 1511LS2 of the first cover part 1511, a position adjacent to the left side 1511SS1 of the first cover part 1511, and a position adjacent to the right side 1511SS2 of the first cover part 1511. Hereinafter, an example is given where the rigid part 160 is positioned adjacent to the upper side 1511LS1 of the first cover part 1511.

The rigid part 160 may include a first rigid part 161. The first rigid part 161 may be coupled to an inner surface of the first cover part 1511. The first rigid part 161 may be positioned adjacent to the upper side 1511LS1 of the first cover part 1511. The first rigid part 161 may be elongated along a longitudinal direction of the upper side 1511LS1 of the first cover part 1511.

The first rigid part 161 may include a first base 1611. The first base 1611 may be in contact with the inner surface of the first cover part 1511. The first base 1611 may be attached to the inner surface of the first cover part 1511. The first base 1611 may be formed in the shape of a flat bar including a flat surface.

A first groove 161g may be formed in the first base 1611. The first groove 161g may be formed on a surface of the first base 1611 that faces the back cover 150. The first groove 161g may be formed in such a manner that the first base 1611 is recessed from the surface facing the back cover 150.

The first rigid part 161 may include a first protruding part 1612. The first protruding part 1612 may protrude from the first base 1611. The first protruding part 1612 may protrude in a direction intersecting a longitudinal direction of the first base 1611. The first protruding part 1612 may protrude in a thickness direction of the first base 1611 and/or a thickness direction the back cover 150. A width of the first protruding part 1612 may be less than a width of the first base 1611. A thickness of the first protruding part 1612 may be greater than a thickness of the first base 1611.

The first base 1611 and the first protruding part 1612 may be formed of the same material. For example, the first base 1611 and the first protruding part 1612 may be formed of engineering plastic. For example, the first base 1611 and the first protruding part 1612 may be formed of a PC material and/or PC-GF material. For example, the first base 1611 and the first protruding part 1612 may be formed of 10% PC-GF.

The first rigid part 161 may include a first flexible part 1613. The first flexible part 1613 may be positioned at a center of the first rigid part 161. The first base 1611 and the first protruding part 1612 may be divided by the first flexible part 1613. The first flexible part 1613 may separate or partition the first base 1611 and the first protruding part 1612. The first flexible part 1613 may have a height corresponding to a height from a lower surface of the first base 1611 to an upper end of the first protruding part 1612. The first flexible part 1613 may have a height corresponding to a height from the first groove 161g of the first base 1611 to the upper end of the first protruding part 1612.

The first base 1611 may include a first part 1611a positioned on one side of the first flexible part 1613, and a second part 1611b positioned on the other side of the first flexible part 1613. The first protruding part 1612 may include a first protruding part 1612a that is positioned on one side of the first flexible part 1613 and on the first part 1611a, and a second protruding part 1612b that is positioned on the other side of the first flexible part 1613 and on the second part 1611b.

The first flexible part 1613 may be formed of a flexible material. The first flexible part 1613 may be formed of an elastic material. For example, the first flexible part 1613 may be formed of silicone.

The first base 1611, the first protruding part 1612, and the first flexible part 1613 may be simultaneously formed by extrusion. For example, the first base 1611, the first protruding part 1612, and the first flexible part 1613 may be formed by dual extrusion (co-extrusion). That is, the first base 1611, the first protruding part 1612, and the first flexible part 1613 may be simultaneously formed through extrusion processing of a dual member.

The rigid part 160 may include a second rigid part 162. The second rigid part 162 may be formed in the same structure as the first rigid part 162.

The second rigid part 162 may be coupled to an inner surface of the second cover part 1512. The second rigid part 162 may be positioned adjacent to the upper side 1511LS1 of the first cover part 1511 on the second cover part 1512. The second rigid part 162 may be elongated along the longitudinal direction of the upper side 1511LS1 of the first cover part 1511.

The second rigid part 162 may include a second base 1621. The second base 1621 may be in contact with the inner surface of the second cover part 1512. The second base 1621 may be attached to the inner surface of the second cover part 1511. The second base 1621 may be formed in the shape of a flat bar including a flat surface.

A second groove 162g may be formed in the second base 1621. The second groove 162g may be formed on a surface of the second base 1621 that faces the back cover 150. The second groove 162g may be formed in such a manner that the second base 1621 is recessed from the surface facing the back cover 150.

The second rigid part 162 may include a second protruding part 1622. The second protruding part 1622 may protrude from the second base 1621. The second protruding part 1622 may protrude in a direction intersecting a longitudinal direction of the second base 1621. A width of the second protruding part 1622 may be less than a width of the second base 1621. A thickness of the second protruding part 1622 may be greater than a thickness of the second base 1621.

The second base 1621 and the second protruding part 1622 may be formed of the same material. For example, the second base 1621 and the second protruding part 1622 may be formed of engineering plastic. For example, the second base 1621 and the second protruding part 1622 may be formed of a PC material and/or PC-GF material. For example, the second base 1621 and the second protruding part 1622 may be formed of 10% PC-GF.

The second rigid part 162 may include a second flexible part 1623. The second flexible part 1623 may be positioned at a center of the second rigid part 162. The second base 1621 and the second protruding part 1622 may be divided by the second flexible part 1623. The second flexible part 1623 may separate or partition the second base 1621 and the second protruding part 1622. The second flexible part 1623 may have a height corresponding to a height from a lower surface of the second base 1621 to an upper end of the second protruding part 1622. The second flexible part 1623 may have a height corresponding to a height from the second groove 162g of the second base 1621 to the upper end of the second protruding part 1622.

The second base 1621 may include a third part 1621a positioned on one side of the second flexible part 1623, and a fourth part 1621b positioned on the other side of the second flexible part 1623. The second protruding part 1622 may include a third protruding part 1622a that is positioned on one side of the second flexible part 1623 and on the third part 1621a, and a fourth protruding part 1622b that is positioned on the other side of the second flexible part 1623 and on the fourth part 1621b.

The second flexible part 1623 may be formed of a flexible material. The second flexible part 1623 may be formed of an elastic material. For example, the second flexible part 1623 may be formed of silicone.

The second base 1621, the second protruding part 1622, and the second flexible part 1623 may be formed by dual extrusion (co-extrusion). For example, the second base 1621, the second protruding part 1622, and the second flexible part 1623 may be simultaneously formed by extrusion molding.

The rigid part 160 may include a connection part 163. The connection part 163 may connect the first rigid part 161 and the second rigid part 162. The connection part 163 may connect the first part 1611a of the first rigid part 161 and the fourth part 1621b of the second rigid part 162. The connection part 163 may be attached to the first cover part 1511. The connection part 163 may be elongated in the longitudinal direction of the upper side 1511LS1 of the first cover part 1511. The connection part 163 may have the shape of a thin rectangular plate. The connection part 163 may be formed of the same material as the first and/or second flexible part 1613, 1623. For example, the connection part 163 may be formed of a flexible material and/or an elastic material. For example, the connection part 163 may be formed of silicone.

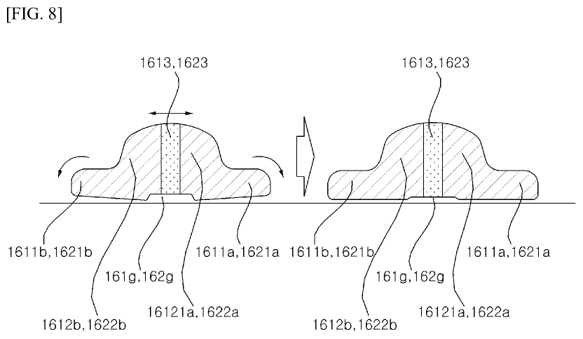

Referring to FIG. 8, the rigid part 160 may undergo extrusion deformation during extrusion molding, or lifting may occur due to the flatness of an object to which the rigid part 160 is attached. In this case, by virtue of the elasticity of the flexible part 1613, 1623, the rigid part 160 can be attached to the attachment object without lifting. Accordingly, it is possible to address the problem of reduced rigidity due to lifting. In addition, even if extrusion deformation or extrusion bending of the rigid part 160 occurs during the extrusion molding process, the elasticity of the flexible part 1613, 1623 allows the rigid part 160 to be attached to the attachment object without lifting. Thus, it is possible to reduce the process defect rate of the rigid part 160, thereby achieving cost savings.

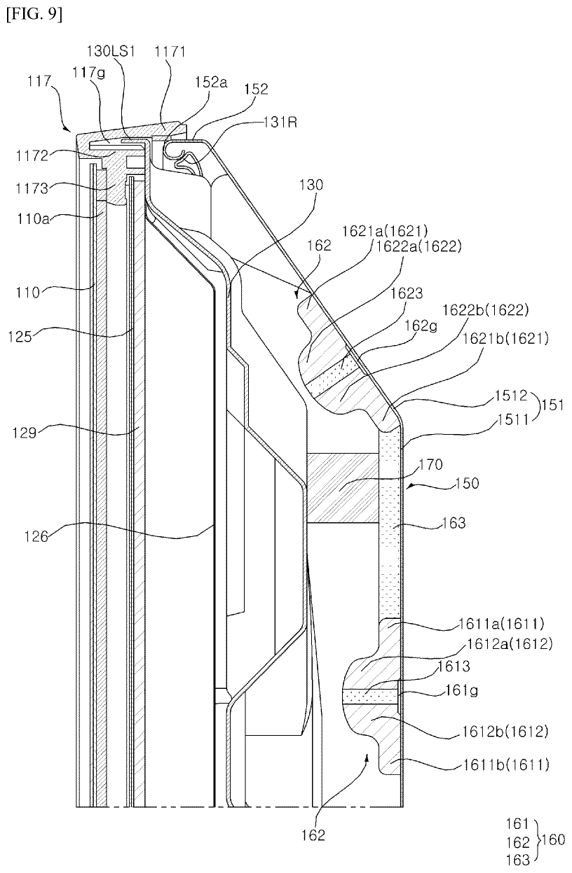

Referring to FIG. 9, the display device 100 may include a shieling member 170. The shielding member 170 may be disposed between the back cover 150 and the frame 130, and may contact each of the back cover 150 and the frame 130. The shielding member 170 may be disposed between the first cover part 1511 and the frame 130. In this case, a portion of the connection part 163 may be cut so that the first cover part 1511 is exposed, and the shielding member 170 may be inserted into the cut portion of the connection part 163 so as to be in contact with and attached to the first cover part 1511. The shielding member 170 may be formed of a conductive material. For example, the shielding member 170 may be an electromagnetic interference (EMI) sponge or an EMI tape. Accordingly, it is possible to reduce EMI noise of the plurality of electronic components installed on the frame 130.

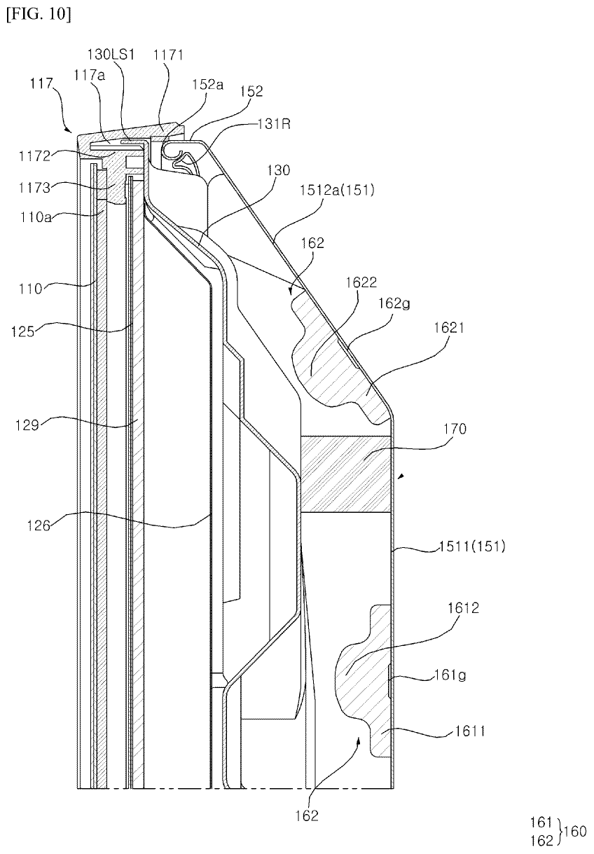

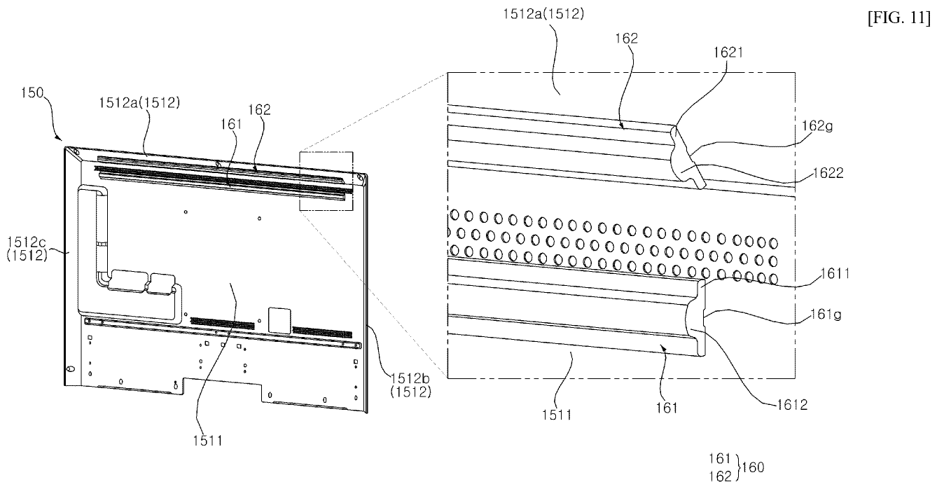

Referring to FIGS. 10 and 11, the rigid part 160 may include a first rigid part 161 and a second rigid part 162. The first rigid part 161 and the second rigid part 162 may be spaced apart from each other. The first rigid part 161 may be attached to the first cover part 1511, and the second rigid part 162 may be attached to the second cover part 1512. The first rigid part 161 and the second rigid part 162 may be positioned adjacent to one side of the first cover part 1511. For example, the first rigid part 161 and the second rigid part 162 may be positioned adjacent to the upper side 1511LS1 of the first cover part 1511.

The first rigid part 161 may include a first base 1611 attached to the first cover part 1511. The first base 1611 may be elongated along a longitudinal direction of the upper side 1511LS1 of the first cover part 1511. The first base 1611 may be formed in the shape of a bar including a flat surface. A first groove 161g may be formed on an attachment surface where the first base 1611 is attached to the first cover part 1511.

The first rigid part 161 may include a first protruding prat 1612. The first protruding prat 1612 may protrude from the first base 1611. The first protruding part 1612 may protrude in a direction intersecting a longitudinal direction of the first base 1611. The first protruding part 1612 may protrude in a thickness direction of the first base 1611 and/or a thickness direction of the back cover 150. A width of the first protruding part 1612 may be less than a width of the first base 1611. A thickness of the first protruding part 1612 may be greater than a thickness of the first base 1611.

The first base 1611 and the first protruding part 1612 may be formed as one body. The first base 1611 and the first protruding part 1612 may be formed of the same material. For example, the first base 1611 and the first protruding part 1612 may be formed of 10% PC-GF. The first base 1611 and the first protruding part 1612 may be formed by extrusion.

The second rigid part 162 may include a second base 1621 attached to the second cover part 1512. The second base 1621 may be elongated along the longitudinal direction of the upper side 1511LS1 of the first cover part 1511. The second base 1621 may be formed in the shape of a bar including a flat surface. A second groove 162g may be formed on an attachment surface where the second base 1621 is attached to the second cover part 1512.

The second rigid part 162 may include a second protruding part 1622. The second protruding part 1622 may protrude from the second base 1621. The second protruding part 1622 may protrude in a direction intersecting a longitudinal direction of the second base 1621. The second protruding part 1622 may protrude in a thickness direction of the second base 1621 and/or the thickness direction of the back cover 150. A width of the second protruding part 1622 may be less than a width of the second base 1621. A thickness of the second protruding part 1622 may be greater than a thickness of the second base 1621.

The base 1621 and the second protruding part 1622 may be formed as one body. The second base 1621 and the second protruding part 1622 may be formed of the same material. For example, the second base 1621 and the second protruding part 1622 may be formed of 10% PC-GF. The second base 1621 and the second protruding part 1622 may be formed by extrusion.

A shielding member 170 may be disposed between the back cover 150 and the frame 130, and may contact each of the back cover 150 and the frame 130. The shielding member 170 may be disposed between the first rigid part 161 and the second rigid part 162. The shielding member 170 may be in contact with the first cover part 1511 between the first rigid part 161 and the second rigid part 162. The shielding member 170 may be formed of a conductive material. For example, the shielding member 170 may be an electromagnetic interference (EMI) sponge or an EMI tape. Accordingly, it is possible to reduce EMI noise of the plurality of electronic components installed on the frame 130.

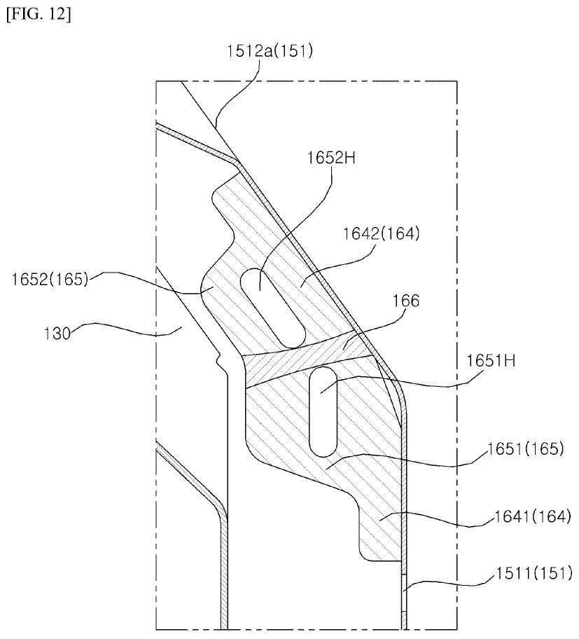

Referring to FIG. 12, a rigid part 160′ may be attached to the back cover 150. The rigid part 160′ may be attached to an inner surface of the back cover 150. The rigid part 160′ may be coupled to a portion where the first cover part 1511 and the second cover part 1512 are connected. The rigid part 160′ may be coupled to an edge of the first cover part 511. The rigid part 160′ may be elongated along a longitudinal direction of one side of the first cover part 1511. For example, the rigid part 160′ may be elongated along a longitudinal direction of the upper side 1511LS1 of the first cover part 1511.

The rigid part 160′ may include a base 164, and a protruding part 165 protruding from the base 164. The base 164 may be attached to the inner surface of the back cover 150. The base 164 may include a first part 1641 attached to the first cover part 1511, and a second part 1642 attached to the second cover part 1512. The first part 1641 may extend from the edge of the first cover part 1511 along an inner surface of the first cover part 1511. The second part 1642 may be connected to the first part 1641, and may extend from the edge of the first cover part 1511 along an inner surface of the second cover part 1512. The first part 1641 and the second part 1642 may form an obtuse angle.

The protruding part 165 may protrude from the base 164 in a thickness direction of the back cover 140 or the base 164. The protruding part 165 may protrude from the base 164 in a direction toward the frame 130. The protruding part 165 may be formed to have a width less than a width of the base 164. The protruding part 165 may include a first protruding part 1651 protruding from the first part 1641, and a second protruding part 1652 protruding from the second part 1642. An upper end of the first protruding part 1651 and an upper end of the second protruding part 1652 may form an obtuse angle. A first hole 1651H may be formed in the first protruding part 1651. The first hole 1651H may be formed through the first protruding part 1651 in a longitudinal direction of the first protruding part 1651. A second hole 1652H1 may be formed in the second protruding part 1652. The second hole 1652H may be formed through the second protruding part 1652 in a longitudinal direction of the second protruding part 1652.

The rigid part 160′ may include a flexible part 166. The flexible part 166 may be positioned at a center of the rigid part 160′. The first part 1641 and the first protruding part 1651 may be positioned on one side of the rigid part 160′, and the second part 1642 and the second protruding part 1652 may be positioned on the other side of the rigid part 160′.

The base 164 and the protruding part 165 may be formed of the same material. For example, the base 164 and the protruding part 165 may be formed of engineering plastic. For example, the base 164 and the protruding part 165 may be formed of a PC material. For example, the base 164 and the protruding part 165 may be formed of 10% PC-GF. The flexible part 166 may be formed of a different material from the base 164 and the protruding part 165. The base 164 and the protruding part 165 may be formed of a flexible material and/or an elastic material. For example, the flexible part 166 may be formed of silicone.

The base 164, the protruding part 165, and the flexible part 166 may be formed by dual extrusion (co-extrusion). The base 164, the protruding part 165, and the flexible part 166 may be simultaneously formed through extrusion processing of a dual member.

As the rigid part 160′ is provided at its center with the flexible part 166, it is possible to suppress or reduce lifting.

According to an aspect of the present disclosure, a display device may include: a display panel 110; a frame 130 to which the display panel 110 is coupled; a back cover 150 coupled to the frame 130 and opposite the display panel 110 with respect to the frame 130; and a rigid part 160 disposed between the frame 130 and the back cover 150, attached to the back cover 150, and elongated in a longitudinal direction of one side of the display panel 110, the rigid part 160 may include: a base 1611, 1621 attached to the back cover 150; and a protruding part 1612, 1622 protruding from the base 1611, 1621 in a thickness direction of the back cover 150.

The rigid part 160 may include a flexible part 1613, 1623 passing through a center of the rigid part 160 in a thickness direction of the rigid part 160 and having elasticity.

The back cover 150 may include: a first cover part 1511 spaced rearward from the frame 130; and a second cover part 1512 extending from an edge of the first cover part 1511 while forming an obtuse angle, and coupled to the frame 130., the rigid part 160 may include: a first rigid part 161 attached to the first cover part 1511 and disposed adjacent to the edge of the first cover part 1511; and a second rigid part 162 attached to the second cover part 1512 and disposed adjacent to an edge of the second cover part 1512.

The base 1611 of the first rigid part 1611 may include: a first part 1611a; and a second part 1611b opposite the first part 1611a with respect to the flexible part 1613, the base 1621 of the second rigid part 162 may include: a third part 1621a adjacent to the second part 1611b; and a fourth part 1621b opposite the third part 1621a with respect to the flexible part 1623.

The rigid part 160 may include a connection part 163 attached to the first cover part 1511, connecting the first rigid part 161 and the second rigid part 162, and having elasticity.

The protruding part 1612 of the first rigid part 161 may include: a first protruding part 1612a protruding from the first part 1611a; and a second protruding part 1612b protruding from the second part 1611b and opposite the first protruding part 1612a with respect to the flexible part 1613, the protruding part 1622 of the second rigid part 162 may include: a third protruding part 1622a protruding from the third part 1621a; and a fourth protruding part 1621b protruding from the fourth part 1621a and opposite the third protruding part 1622a with respect to the flexible part 1623.

The base 1611, 1612 may include: a groove 161g, 162g formed on an attachment surface where the base 1611, 1612 is attached to the back cover 150, and recessed from the attachment surface toward the protruding part 1612, 1622, the flexible part 1613, 1623 may be positioned through the groove 161g, 162g and the protruding part 1612, 1622 in the thickness direction of the back cover 150.

The display device may further include a shielding member 170 that is disposed between the back cover 150 and the frame 130, in contact with each of the back cover 150 and the frame 130, and positioned between the first rigid part 161 and the second rigid part 162 on the first cover part 1511.

The display device may further include a shielding member 170 that is disposed between the back cover 150 and the frame 130, in contact with each of the back cover 150 and the frame 130, and positioned between the first rigid part 161 and the second rigid part 162 on the first cover part 1511, the back cover 150 may include an exposed portion exposed by cutting a portion of the connection part 163. The shielding member 170 may be in contact with the exposed portion of the back cover 150.

A width of the protruding part 1612, 1622 may be less than a width of the base 1611, 1621, and a thickness of the protruding part 1612, 1622 may be greater than a thickness of the base 1611, 1621.

The base 1611, 1621 and the protruding part 1621, 1622 may be formed of a same material, the flexible part 1613, 1623 may be formed of a different material from the base 1611, 1621 and the protruding part 1612, 1622, the base 1611, 1621, the protruding part 1621, 1622, and the flexible part 1613, 1623 may be formed by co-extrusion.

The back cover 150 may include: a first cover part 1511 spaced rearward from the frame 130; and a second cover part 1512 extending from an edge of the first cover part 1511 while forming an obtuse angle, and coupled to the frame 130, the rigid part 160′ may be attached to the edge of the back cover 150, the base 164 of the rigid part 160′ may include: a first part 1641 attached to the first cover part 1511 and extending from the edge of the back cover 150 along an inner surface of the first cover part 1511; and a second part 1642 attached to second cover part 1512, extending from the edge of the back cover 150 along an inner surface of the second cover part 1512, and forming an obtuse angle with respect to the first part 1641.

The protruding part 165 of the rigid part 160′ may include: a first protruding part 1651 protruding from the first part 1641 with a smaller width than the first part 1641; and a second protruding part 1652 protruding from the second part 1642 with a smaller width than the second part 1642 and forming an obtuse angle with the first protruding part 1651.

The rigid part 160′ may include: a first hole 1651H formed in the first protruding part 1651; a second hole 1652H formed in the second protruding part 1652; and a flexible part 166 having elasticity, elongated in a longitudinal direction of the rigid part 160′, and passing through the rigid part 160′ in a thickness direction of the rigid part 160′ between the first hole 1651H and the second hole 1652H.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings, and a configuration “B” described in another embodiment of the disclosure and the drawings may be combined with each other. Namely, although the combination between the configurations is not directly described, the combination is possible except in the case where it is described that the combination is impossible.

The above detailed description is to be construed in all aspects as illustrative and not restrictive. The scope of the present disclosure should be determined by reasonable interpretation of the appended claims, and all changes coming within the equivalency range of the present disclosure are intended to be embraced in the scope of the present disclosure.

1. A display device comprising:
a display panel;
a frame to which the display panel is coupled;
a back cover coupled to the frame and opposite the display panel with respect to the frame; and
a rigid part disposed between the frame and the back cover, attached to the back cover, and elongated in a longitudinal direction of one side of the display panel,
wherein the rigid part comprises:
a base attached to the back cover; and
a protruding part protruding from the base in a thickness direction of the back cover.

2. The display device of claim 1, wherein the rigid part comprises a flexible part passing through a center of the rigid part in a thickness direction of the rigid part, and having elasticity.

3. The display device of claim 2, wherein the back cover comprises:
a first cover part spaced rearward from the frame; and
a second cover part extending from an edge of the first cover part while forming an obtuse angle, and coupled to the frame, and
wherein the rigid part comprises:
a first rigid part attached to the first cover part and disposed adjacent to the edge of the first cover part; and
a second rigid part attached to the second cover part and disposed adjacent to an edge of the second cover part.

4. The display device of claim 3, wherein the base of the first rigid part comprises:
a first part; and
a second part opposite the first part with respect to the flexible part, and
wherein the base of the second rigid part comprises:
a third part adjacent to the second part; and
a fourth part opposite the third part with respect to the flexible part.

5. The display device of claim 4, wherein the rigid part comprises a connection part attached to the first cover part, connecting the first rigid part and the second rigid part, and having elasticity.

6. The display device of claim 4, wherein the protruding part of the first rigid part comprises:
a first protruding part protruding from the first part; and
a second protruding part protruding from the second part, and opposite the first protruding part with respect to the flexible part, and
wherein the protruding part of the second rigid part comprises:
a third protruding part protruding from the third part; and
a fourth protruding part protruding from the fourth part, and opposite the third protruding part with respect to the flexible part.

7. The display device of claim 2, wherein the base comprises a groove formed on an attachment surface where the base is attached to the back cover, and recessed from the attachment surface toward the protruding part, and
wherein the flexible part is positioned through the groove and the protruding part in the thickness direction of the back cover.

8. The display device of claim 3, further comprising a shielding member that is disposed between the back cover and the frame, in contact with each of the back cover and the frame, and positioned between the first rigid part and the second rigid part on the first cover part.

9. The display device of claim 5, further comprising a shielding member that is disposed between the back cover and the frame, in contact with each of the back cover and the frame, and positioned between the first rigid part and the second rigid part on the first cover part,
wherein the back cover comprises an exposed portion exposed by cutting a portion of the connection part, and
wherein the shielding member is in contact with the exposed portion of the back cover.

10. The display device of claim 1, wherein:
a width of the protruding part is less than a width of the base; and
a thickness of the protruding part is greater than a thickness of the base.

11. The display device of claim 2, wherein the base and the protruding part are formed of a same material,
wherein the flexible part is formed of a different material from the base and the protruding part, and
wherein the base, the protruding part, and the flexible part are formed by co-extrusion.

12. The display device of claim 1, wherein the back cover comprises:
a first cover part spaced rearward from the frame; and
a second cover part extending from an edge of the first cover part while forming an obtuse angle, and coupled to the frame,
wherein the rigid part is attached to the edge of the back cover,
wherein the base of the rigid part comprises:
a first part attached to the first cover part and extending from the edge of the back cover along an inner surface of the first cover part; and
a second part attached to the second cover part, extending from the edge of the back cover along an inner surface of the second cover part, and forming an obtuse angle with respect to the first part.

13. The display device of claim 12, wherein the protruding part of the rigid part comprises:
a first protruding part protruding from the first part with a smaller width than the first part; and
a second protruding part protruding from the second part with a smaller width than the second part, and forming an obtuse angle with the first protruding part.

14. The display device of claim 13, wherein the rigid part comprises:
a first hole formed in the first protruding part;
a second hole formed in the second protruding part; and
a flexible part having elasticity, elongated in a longitudinal direction of the rigid part, and passing through the rigid part in a thickness direction of the rigid part between the first hole and the second hole.
